(19) United States
(12) Patent Application Publication
(10) Pub. No.: US 2012/0326580 A1
(43) Pub. Date: Dec. 27, 2012

(54) ELECTRONIC DEVICE ENCLOSURE

(75) Inventors: XU-DONG NAN, Wuhan City (CN); ZHI-PING WU, Wuhan City (CN); CHAO LIU, Wuhan City (CN); NAI-JUAN LI, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/414,851

(22) Filed: Mar. 8, 2012

(30) Foreign Application Priority Data
Jun. 24, 2011 (CN) 201110173060.X

(51) Int. Cl. H05K 5/02; H05K 7/18

(52) U.S. Cl. 312/223.2

(57) ABSTRACT

An electronic device enclosure which is able to resist damage from jolts or bumping includes a frame, a limiting member located in the frame, a cover secured to the frame, a mounting bracket and a blocking member. The frame includes a side plate. The mounting bracket is adapted to receive a data storage device and includes a first sidewall and a second sidewall opposite to the first sidewall. The second sidewall is secured to the side plate. A first end of the first sidewall is rotatably received in the limiting member and located between the limiting member and the second sidewall. A second end of the first sidewall opposite to the first end is hung on the frame. The blocking member is secured to the cover and abuts the second end. The second end is located between the blocking member and the second sidewall.

### BACKGROUND

1. Technical Field

The present disclosure relates to electronic device enclosures, and particularly to an electronic device enclosure of a server or a computer.

2. Description of Related Art

A data storage device, such as a hard disk drive, may be secured to a mounting bracket, and then the mounting bracket is secured to an enclosure of a computer or a server. The mounting bracket may have two sidewalls. One sidewall is secured to a side plate of the enclosure. A first end of the other sidewall is rotatably mounted to a mounting plate in the enclosure. A second end of the other sidewall opposite the first end is hung on the enclosure. When the mounting bracket is jolted, the other sidewall may easily be deformed and cause the data storage device to disengage from the mounting bracket.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of an electronic device enclosure and a data storage device.

FIG. 2 is similar to FIG. 1, but viewed from a different aspect.

FIG. 3 is an assembled, isometric view of a cover and a blocking member, but viewed from a different aspect.

FIG. 4 is an isometric view of the assembled electronic device enclosure and the data storage device of FIG. 1, but not showing the cover.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

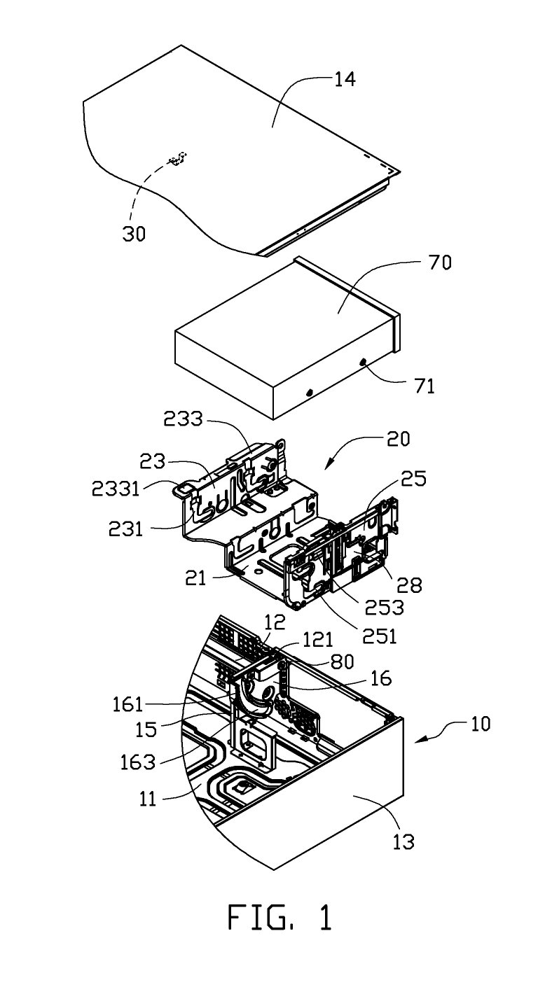

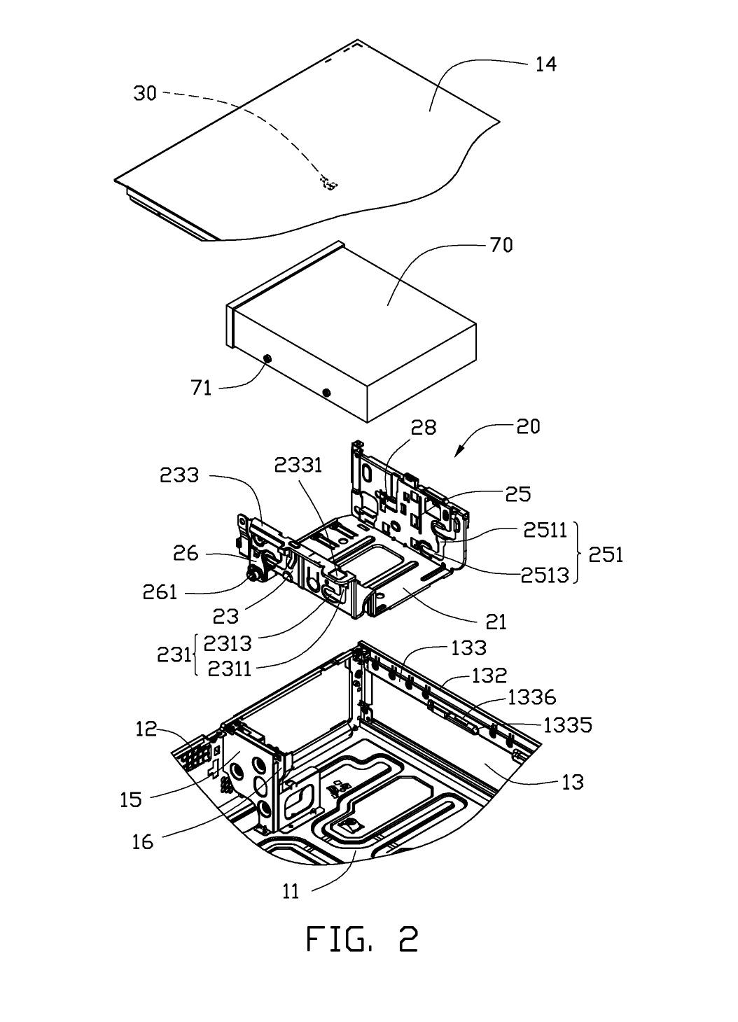

Referring to FIG. 1 and FIG. 2, an electronic device enclosure in accordance with an embodiment includes a frame 10, a mounting bracket 20 and a cover 14.

The frame 10 includes a bottom plate 11, a front plate 12 and a side plate 13. The cover 14 can be secured to the front plate 12 and the side plate 13. In one embodiment, the bottom plate 11 is substantially parallel to the cover 14, and the front plate 12 is substantially perpendicular to the cover 14 and the side plate 13. A mounting piece 121 extends from the front plate 12. The mounting piece 121 is substantially parallel to the bottom plate 11. A bracket 15 is secured to the bottom plate 11 and the mounting piece 121. A limiting member 16 is secured to the bracket 15 and the mounting piece 121 and faces the side plate 13. The limiting member 16 includes two limiting pieces 161. A limiting slot 163 is defined between the two limiting pieces 161. In one embodiment, the two limiting pieces 161 are curved, and the limiting slot 163 is curved. A flange 132 extends from a top edge of the side plate 13. A mounting plate 133 extends from the flange 132. In one embodiment, the flange 132 is substantially perpendicular to the side plate 13, and the mounting plate 133 is substantially parallel to the side plate 13. The mounting plate 133 includes two mounting portions 1335. Each of the two mounting portions 1335 defines a mounting hole 1336.

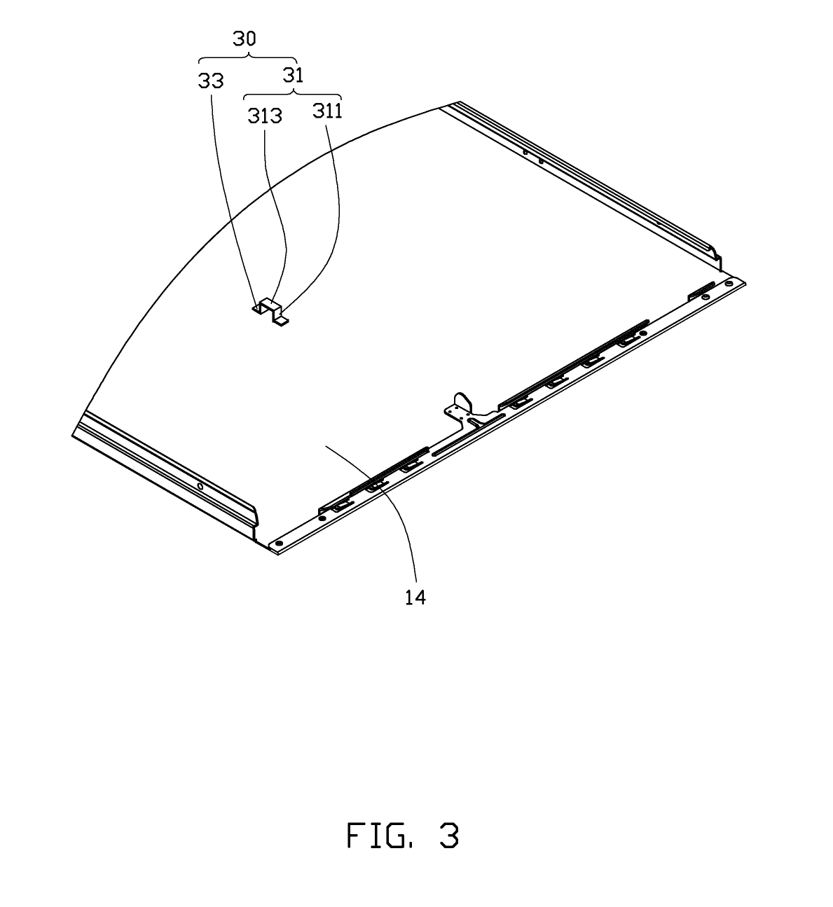

Referring to FIG. 3, a blocking member 30 is secured to the cover 14 by soldering, riveting or other securing methods. The blocking member 30 includes a blocking portion 31 and two mounting pieces 33 connected to the blocking portion 31. The blocking portion 31 includes two blocking pieces 311 and a connecting piece 313. In one embodiment, the two blocking pieces 311 are substantially parallel to each other, and the two blocking pieces 311 are substantially perpendicular to the connecting piece 312. Each of the two mounting pieces 33 extends from a top edge of each of the two blocking pieces 311. The two mounting pieces 33 extend along two opposite directions and are substantially perpendicular to the two blocking pieces 311. In one embodiment, the two mounting pieces 33 are located in one plane.

The mounting bracket 20 includes a bottom wall 21, a first sidewall 23 and a second sidewall 25 opposite to the first sidewall 23. The first sidewall 23 and the second sidewall 25 are connected substantially perpendicularly to the bottom wall 21. A limiting plate 233 extends from a top edge of the first sidewall 23. The first sidewall 23 defines two first securing slots 231. The limiting plate 233 includes a recess portion 2331. The limiting plate 233 can be pressed through the recess portion 2331. Each of the two first securing slots 231 includes a first inserting portion 2311 and a first receiving portion 2313. The first inserting portion 2311 is substantially perpendicular to the bottom wall 21. The first receiving portion 2313 is substantially parallel to the bottom wall 21 and communicates with the first inserting portion 2311. A sliding member 26 is secured to a first end of the first sidewall 23 away from the recess portion 2331. A sliding block 261 protrudes from the sliding member 26. A second end of the first sidewall 23 adjacent to the recess portion 2331 is hung on the frame 10. The second sidewall 25 defines two second securing slots 251. Each of the two second securing slots 251 includes a second inserting portion 2511 and a second receiving portion 2513. The second inserting portion 2511 is substantially perpendicular to the bottom wall 21. The second receiving portion 2513 is substantially parallel to the bottom wall 21 and communicates with the second inserting portion 2511. Two latching portions 253 extend from the second sidewall 25 and these can be secured to the two mounting portions 1335. A positioning member 28 is secured to the second sidewall 25.

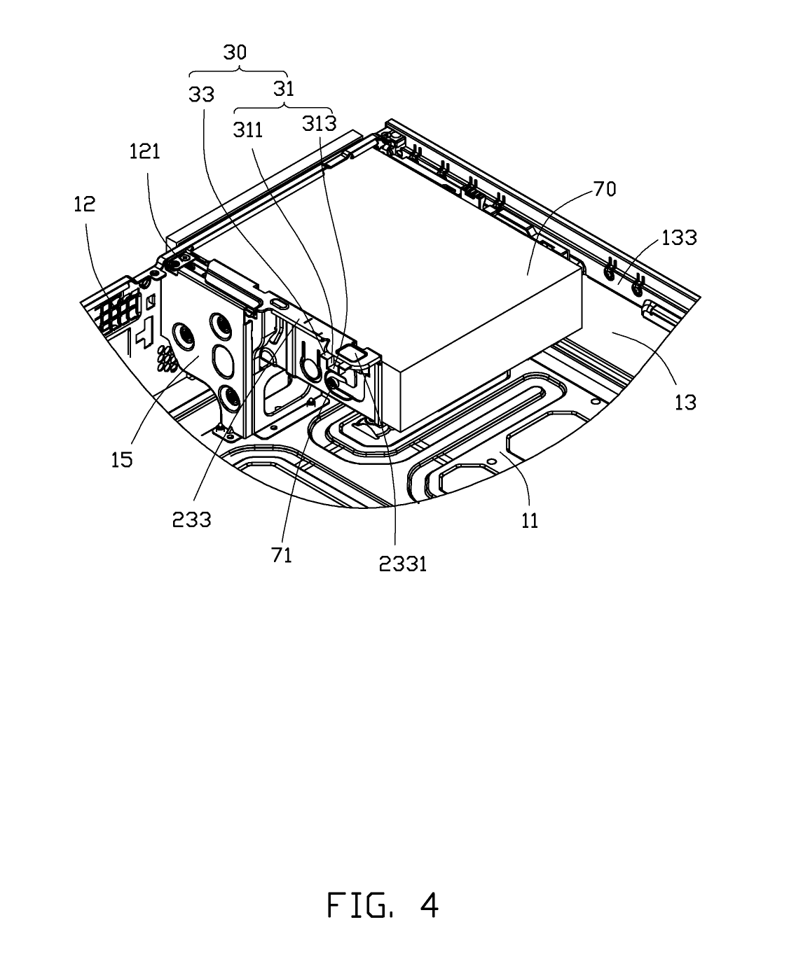

Referring to FIG. 4, in assembly, the mounting bracket 20 is moved towards the frame 10, and the second sidewall 25 is adjacent to the side plate 13. The first sidewall 23 is rotatably mounted to the limiting member 16 by means of a shaft 80. The first end of the second sidewall 25 is rotatably mounted to the mounting plate 133 by means of another shaft 80. The sliding block 261 is received in the limiting slot 163. When the recess portion 1332 is pressed to rotate the mounting bracket 20, the sliding block is slid in the limiting slot 163. When the two latching portions 253 actually engages in the mounting hole 1336, the mounting bracket 20 is secured to the frame 10.

The mounting bracket 20 is capable of securing a data storage device 70. Two installing members 71 are located on each of two opposite sides of the data storage device 70. The installing members 71 are inserted from the first inserting portion 2311 and the second inserting portion 2511, and then received in the first receiving portion 2313 and the second receiving portion 2513. The installing members 71 are slidable in the first receiving portion 2313 and the second receiving portion 2513. The positioning member 28 blocks one installing member 71, to prevent the data storage device 70 from moving in the first securing slot 231 and the second securing slot 251.

The cover 14 is secured to the front plate 12 and the side plate 13. The two blocking pieces 311 abut the limiting plate 233. The limiting plate 233 is located between the two blocking pieces 311 and the second sidewall 25. The blocking pieces 311 are substantially perpendicular to the limiting plate 233.

When the mounting bracket 20 is jolted or vibrated along a direction substantially perpendicular to the side plate 13, the blocking member 30 prevents the first sidewall 23 from deforming away from the side plate 13. Thus, the data storage device 70 is prevented from moving away from the side plate 13 and disengaging from the second sidewall 25. When the mounting bracket 20 is bumped, the force of the bumping or jolting is taken by the limiting member 16 and the bracket 15. The blocking member 30 only receives a small part of the force and will transfer this to the cover 14. Thus, the direct force suffered by the limiting member 16 and the bracket 15 is much reduced.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An electronic device enclosure comprising:
a frame comprising a side plate;
a limiting member located in the frame;
a cover secured to the frame;
a mounting bracket adapted for receiving a data storage device and comprising a first sidewall and a second sidewall opposite to the first sidewall, the second sidewall secured to the side plate, and a first end of the first sidewall rotatably received in the limiting member and located between the limiting member and the second sidewall; and a second end of the first sidewall opposite to the first end hung on the frame; and
a blocking member secured to the cover and abutting the second end of first sidewall, the second end of the first sidewall is located between the blocking member and the second sidewall;
wherein when the data storage device is secured to the mounting bracket, the first sidewall is located between the data storage device and the blocking member.

2. The electronic device enclosure of claim 1, wherein the blocking member comprises a blocking portion and two mounting pieces connected to the blocking portion, the two mounting pieces are secured to the cover, and the blocking portion abuts the first sidewall.

3. The electronic device enclosure of claim 2, wherein the blocking portion comprises two blocking pieces and a connecting piece connected to the two blocking pieces, the two blocking pieces abut the first sidewall, and the two blocking pieces are substantially parallel to each other.

4. The electronic device enclosure of claim 3, wherein the two blocking pieces are substantially perpendicular to the first sidewall and the cover.

5. The electronic device enclosure of claim 3, wherein each of the two mounting pieces extends from each of the two blocking pieces, the two mounting pieces extend along two opposite directions, and the two mounting pieces are substantially perpendicular to the two blocking pieces.

6. The electronic device enclosure of claim 1, wherein each of the first sidewall and the second sidewall defines a securing slot adapted to receive an installing member secured to the data storage device, the securing slot comprises an inserting portion and a receiving portion, and the inserting portion is substantially perpendicular to the receiving portion and communicates with the receiving portion.

7. The electronic device enclosure of claim 1, wherein a limiting plate extends from the first sidewall away from the second sidewall, the limiting plate is substantially perpendicular to the first sidewall and abuts the blocking member.

8. The electronic device enclosure of claim 7, wherein the limiting member comprises two limiting pieces, a limiting slot is defined between the two limiting pieces, and the a sliding member is secured to the first sidewall; a sliding block protrudes from the sliding member, and the sliding block is rotatably received in the limiting slot.

9. The electronic device enclosure of claim 8, wherein a recess portion is located in the liming plate and adjacent to the blocking member, the mounting bracket is rotatable relative to the sliding member by pressing the recess portion.

10. The electronic device enclosure of claim 8, wherein the two limiting pieces and the limiting slot are curved.

11. An electronic device enclosure comprising:
a frame comprising a side plate;
a limiting member located in the frame;
a cover secured to the frame;
a mounting bracket adapted to receive a data storage device and comprising a first sidewall and a second sidewall opposite to the first sidewall, the second sidewall secured to the side plate, and a first end of the first sidewall rotatably received in the limiting member and located between the limiting member and the second sidewall; and a second end of the first sidewall opposite to the first end hung on the frame, and a limiting plate extending from the first sidewall; and
a blocking member secured to the cover and abutting the limiting plate, and the second end of the first sidewall located between the blocking member and the second sidewall;
wherein a recess portion is located in the liming plate, and the mounting bracket is rotatable relative to the limiting member by pressing the recess portion; when the data storage device is secured to the mounting bracket, the first sidewall is located between the data storage device and the blocking member.

12. The electronic device enclosure of claim 11, wherein the blocking member comprises a blocking portion and two mounting pieces connected to the blocking portion, the two mounting pieces are secured to the cover, and the blocking portion abuts the first sidewall.

13. The electronic device enclosure of claim 12, wherein the blocking portion comprises two blocking pieces and a connecting piece connected to the two blocking pieces, the two blocking pieces abut the firs sidewall, and the two blocking pieces are substantially parallel to each other.

14. The electronic device enclosure of claim 13, wherein the two blocking pieces are substantially perpendicular to the first sidewall and the cover.

15. The electronic device enclosure of claim 13, wherein each of the two mounting pieces extends from each of the two blocking pieces, the two mounting pieces extend along two opposite directions, and the two mounting pieces are substantially perpendicular to the two blocking pieces.

16. The electronic device enclosure of claim 11, wherein each of the first sidewall and the second sidewall defines a securing slot adapted to receive an installing member secured to the data storage device, the securing slot comprises an inserting portion and a receiving portion, and the inserting portion is substantially perpendicular to the receiving portion and communicates with the receiving portion.

17. The electronic device enclosure of claim 11, wherein the limiting plate is substantially perpendicular to the first sidewall and abuts the blocking member.

18. The electronic device enclosure of claim 11, wherein the recess portion is adjacent to the blocking member and the second end of the first sidewall.

19. The electronic device enclosure of claim 11, wherein the limiting member comprises two limiting pieces, a limiting slot is defined between the two limiting pieces, and the a sliding member is secured to the first sidewall; a sliding block protrudes from the sliding member, and the sliding block is rotatably received in the limiting slot.

20. The electronic device enclosure of claim 19, wherein the two limiting pieces and the limiting slot are curved.
